(19) United States
(12) Patent Application Publication
(10) Pub. No.: US 2013/0271908 A1
(43) Pub. Date: Oct. 17, 2013

(54) BACK COVER FOR A PANEL MODULE AND FLAT PANEL DISPLAY THEREWITH

(71) Applicants: Hung-Ta Yu, New Taipei City (TW); Jui-Chuan Chien, New Taipei City (TW); Kwang-Tao Chen, New Taipei City (TW)

(72) Inventors: Hung-Ta Yu, New Taipei City (TW); Jui-Chuan Chien, New Taipei City (TW); Kwang-Tao Chen, New Taipei City (TW)

(21) Appl. No.: 13/476,022

(22) Filed: May 21, 2012

(30) Foreign Application Priority Data
Apr. 12, 2012 (TW) 101112970

(51) Int. Cl. H05K 5/03

(52) U.S. Cl. 361/679.21; 312/223.1

(57) ABSTRACT

A back cover for panel module is disclosed and includes a back cover body and a plurality of enhancing parts. The back cover body has a plurality of fixing portions. The perpendicular distance from the fixing portion to a neighboring long edge of the back cover body is about one-third of a length of a wide edge of the back cover body; the perpendicular distance from the fixing part to a neighboring wide edge of the back cover body is about one-third of a length of a long edge of the back cover body. Each enhancing part has two ends which are fixed at one of the fixing portions and a neighboring corner of the back cover body respectively. Thereby, when the flat panel display is increased in size and thinned, the enhancing parts still can effectively improve the structural strength and anti-bending ability of the back cover body.

### BACKGROUND OF THE INVENTION

1. Field of the Invention

The invention relates to a back cover for a panel module, and especially relates to a back cover having enhancing structure.

2. Description of the Prior Art

Current liquid crystal displays or plasma televisions are still under developing. Especially for edge-lighting flat panel displays, thinning is a tendency. Large-sized and thin flat panel displays is becoming mainstream products because the technology thereof is matured. However, as the size becomes larger, the strength of the panel structure needs to be stronger for the quality stability. One of structural supports of the whole panel module is the back cover of the panel. As the size becomes larger, it is more difficult to control bending of the back cover. When bending occurs on the back cover, the bending tends to induce damage to the internal structure of the panel enclosed by the back cover. An example is cracks in the glass of the panel.

In general, simple enhancing ribs are added onto the back cover of the panel in the prior art. The enhancing ribs extend in vertical and horizontal directions so as to enhance the structural strength of the back cover. However, such enhancing ribs cannot satisfy the requirements for large-sized and thin flat panel displays. For example, when a flat panel display with the abovementioned enhancing ribs is loaded with a force perpendicular to the panel thereof, the extent of bending occurring thereon is still too large to induce damage to the flat panel display.

### SUMMARY OF THE INVENTION

An objective of the invention is to provide a back cover designed to improve bending extent on a panel, so as to effectively solve the problems in the prior art.

An embodiment according to the invention discloses a back cover of a panel module. The back cover includes a back cover body and a plurality of enhancing parts. The back cover body includes a plurality of fixing portions. A perpendicular distance from each fixing portion to a neighboring long edge of the back cover body is about one-third of a length of a wide edge of the back cover body. A perpendicular distance from each fixing portion to a neighboring wide edge of the back cover body is about one-third of a length of a long edge of the back cover body. Each enhancing part has a first end and a second end. The first end and the second end of each enhancing part are fixed at one of the fixing portions and a neighboring corner of the back cover body respectively.

Another embodiment according to the invention discloses a flat panel display. The flat panel display includes a panel module and a rear cover. The panel module includes a panel body and a back cover. The panel body is fixed in the back cover. The back cover includes a back cover body and a plurality of enhancing parts. The back cover body includes fixing portions. A perpendicular distance from each fixing portion to a neighboring long edge of the back cover body is about one-third of a length of a wide edge of the back cover body. A perpendicular distance from each fixing portion to a neighboring wide edge of the back cover body is about one-third of a length of a long edge of the back cover body. Each enhancing part has a first end and a second end. The first end and the second end of each enhancing part are fixed at one of the fixing portions and a neighboring corner of the back cover body respectively. The rear cover is joined to a side of the back cover of the panel module.

Another embodiment according to the invention discloses a back cover of a panel module. The back cover includes a back cover body and a plurality of enhancing parts. The back cover body includes a plurality of fixing portions. A perpendicular distance from each fixing portion to a neighboring edge of the back cover body is about one-third of a length of the back cover body along the perpendicular distance. Each enhancing part has a first end and a second end. The first end and the second end of each enhancing part are fixed at one of the fixing portions and a neighboring corner of the back cover body respectively.

In the back cover or the flat panel display according to the invention, the back cover body further comprises an enhancing rib. The enhancing parts are fixed on the enhancing rib. The enhancing parts and the enhancing rib are formed on the back cover body by stamping the back cover body, or the enhancing parts are fixed on the enhancing rib by blind rivets, rivets, or screws or by welding.

In the back cover or the flat panel display according to the invention, an included angle between an extension direction of each enhancing part on the back cover body and the long edge of the back cover body is from 27 to 50 degrees.

In the back cover or the flat panel display according to the invention, the enhancing parts are made of galvanized steel, stainless steel, aluminum alloy, or plastics and are fixed on the back cover body by blind rivets, rivets, or screws or by welding.

In the back cover or the flat panel display according to the invention, the first end of each enhancing part has a wall-mount part. The back cover is capable of being mounted on a wall by use of the wall-mount parts of the enhancing parts.

The back cover and the flat panel display therewith according to the invention can enhance the rigidity of the panel module so as to greatly reduce the bending extent on the large-sized panel module or the flat panel display loaded with an external force, which improves the yield of the flat panel display.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a back cover for a panel module of a first embodiment according to the invention.

FIG. 2 and FIG. 3 are schematic diagrams in different viewpoints illustrating a back cover for a panel module according to a second embodiment.

FIG. 4 is schematic diagram illustrating a back cover for a panel module according to a third embodiment.

FIG. 5 is a partial sectional view of a flat panel display of an embodiment according to the invention.

### DETAILED DESCRIPTION

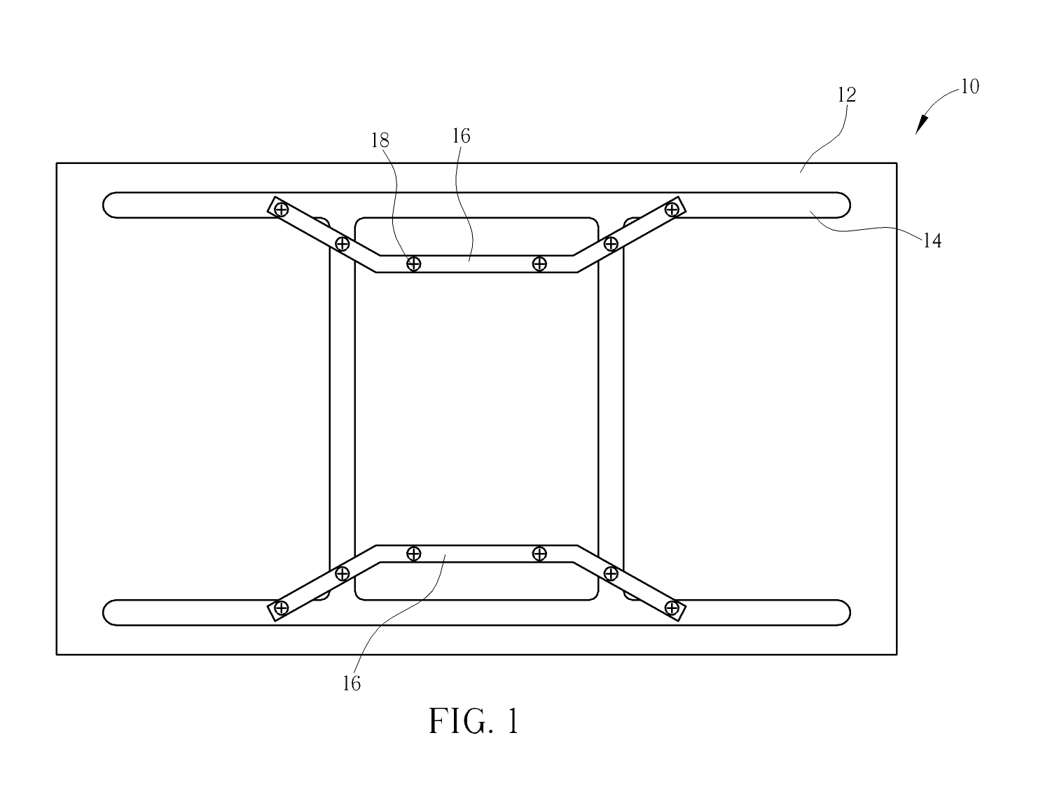

Please refer to FIG. 1, which is a schematic diagram illustrating a back cover 10 for a panel module of a first embodiment according to the invention. A back cover body 12 of the back cover 10 thereon has an II-shaped enhancing rib 14. An enhancing part 16 is fixed on the upper and lower portions of the enhancing rib 14 respectively. The enhancing parts 16 are fixed on the enhancing rib 14 by screws 18 so as to enhance the anti-bending ability of the back cover 10.

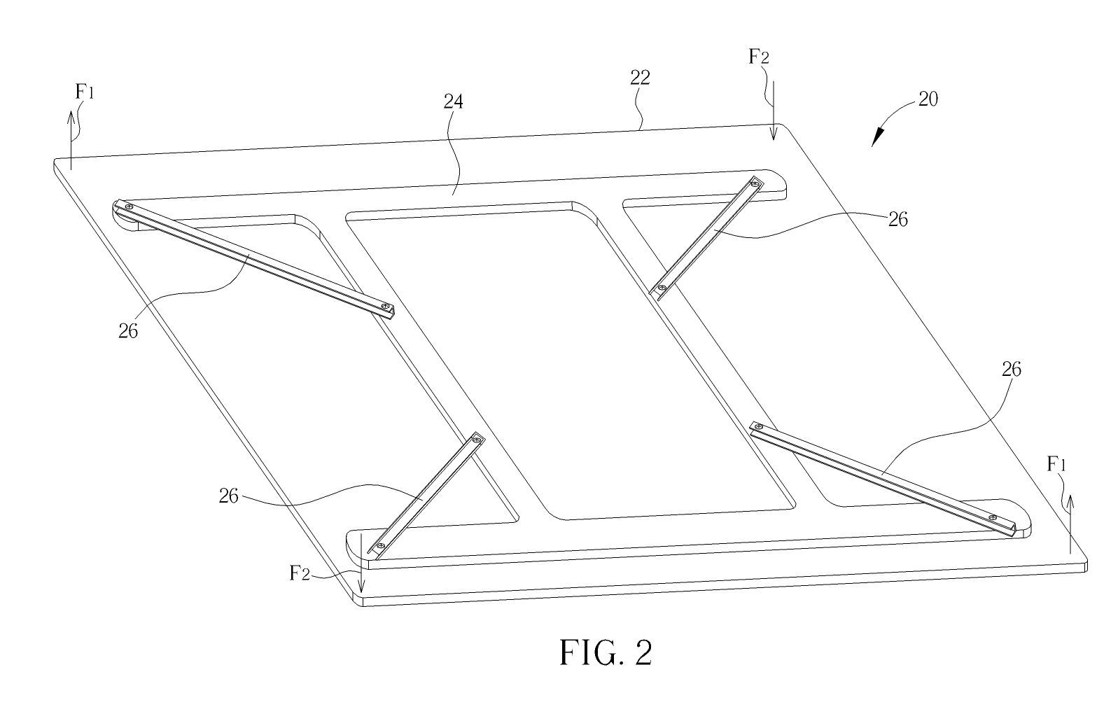

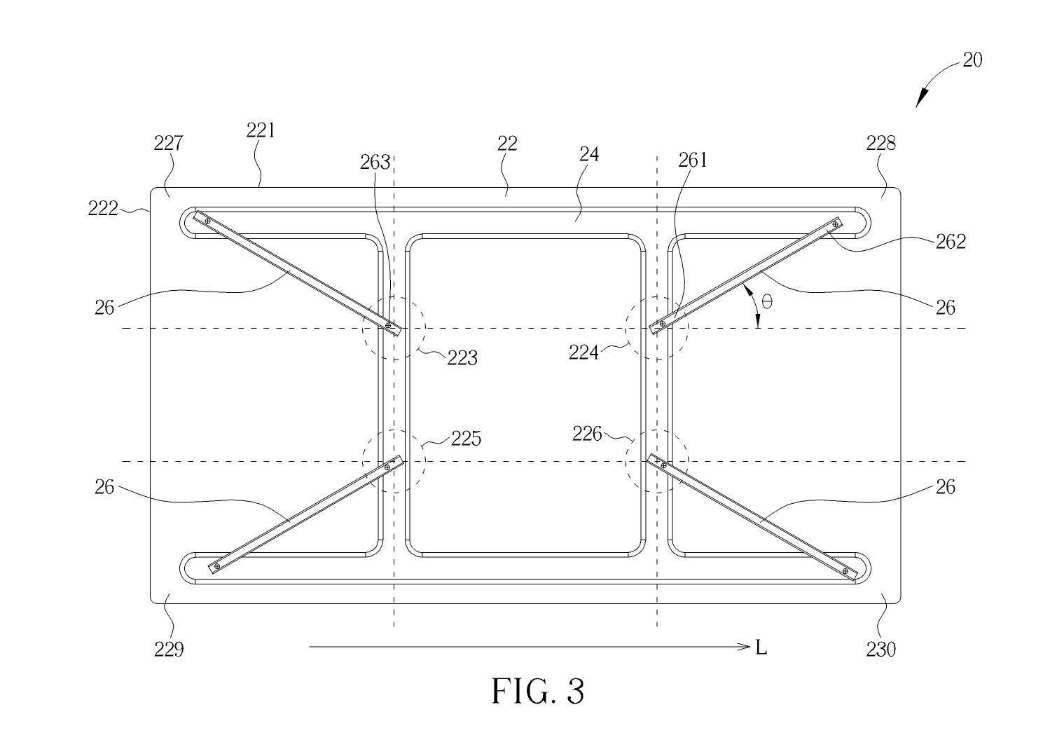

Please refer to FIG. 2 and FIG. 3. FIG. 2 and FIG. 3 are schematic diagrams illustrating a back cover 20 for a panel module of a second embodiment according to the invention. The back cover 20 includes a back cover body 22 and a plurality of enhancing parts 26. The back cover body 22 thereon has an II-shaped enhancing rib 24, which is formed on the back cover body 22 by stamping. The enhancing parts 26 are fixed on the enhancing rib 24.

Please refer to FIG. 3. As shown in FIG. 3, the enhancing parts 26 of the back cover 20 are disposed on the back cover body 22 so as to enhance the anti-bending ability of the back cover body 22 effectively. The back cover body 22 has a plurality of fixing portions 223 through 226. A plurality of corners 227 through 230 of the back cover body 22 are labeled in FIG. 3. For further details, because current flat panel displays mostly have a transverse rectangle appearance of 16:9 or 16:10, it is preferred that the back cover body 22 has at least four fixing portions 223 through 226 and four corners 227 through 230. Therein, the perpendicular distance from each fixing portion 223 through 226 to a neighboring long edge 221 of the back cover body 22 is about one-third of the length of the wide edge 222 of the back cover body 22. Similarly, the perpendicular distance from each fixing portion 223 through 226 to a neighboring wide edge 222 of the back cover body 22 is about one-third of the length of the long edge 221 of the back cover body 22, as shown in FIG. 3. In other words, the perpendicular distance from each fixing portion 223 through 226 to the neighboring edge 221 or 222 of the back cover body 22 is about one-third of the length of the back cover body 22 along the perpendicular distance. In the embodiment, the four fixing portions 223 through 226 are preferred to be located substantially at the intersections of the dashed lines trisecting the long edges 221 and the wide edges 222 respectively, so the distance from each fixing portion 223 through 226 to the neighboring edge 221 or 222 is about one-third of the length of the edge 222 or 221. In the embodiment shown in FIG. 3, at least four enhancing parts 26 are used for the back cover 20 accordingly. The enhancing parts 26 can be made of galvanized steel, stainless steel, aluminum alloy, or plastics in form of long bar. As shown in FIG. 2, the enhancing parts 26 are made in form of C-beam, so that the rigidity of the enhancing part 26 can be preserved to a certain extent even with reduction in volume. Each enhancing part 26 has a first end 261 and a second end 262 which are fixed by blind rivets, rivets, or screws or by welding on the enhancing rib 24 or directly on the back cover body 22 when the enhancing rib 24 is absent.

In the embodiment, the first end 261 and the second end 262 of each enhancing part 26 are fixed on one of the fixing portions 223 through 226 of the back cover body 22 (or the enhancing rib 24 of the back cover body 22) and one of the neighboring corners 227 through 230 respectively. That is, the first end 261 of each enhancing part 26 is fixed about or at one of the intersections of dashed lines trisecting the lengths of the back cover body 22; the second end 262 of each enhancing part 26 is fixed at one of the neighboring corners 227 through 230. For example, in FIG. 3, the first end 261 of one of the enhancing parts 26 is fixed near the fixing portion 224; the second end 262 is fixed at the corner 228. The fixing for the other enhancing parts 26 is similar and will not be repeated additionally herein. In other words, the enhancing parts 26 fixed on the back cover body 22 (or the enhancing rib 24) extend in a radial form from about the intersections of the dashed lines trisecting the lengths of the back cover body 22 to the corners 227 through 230.

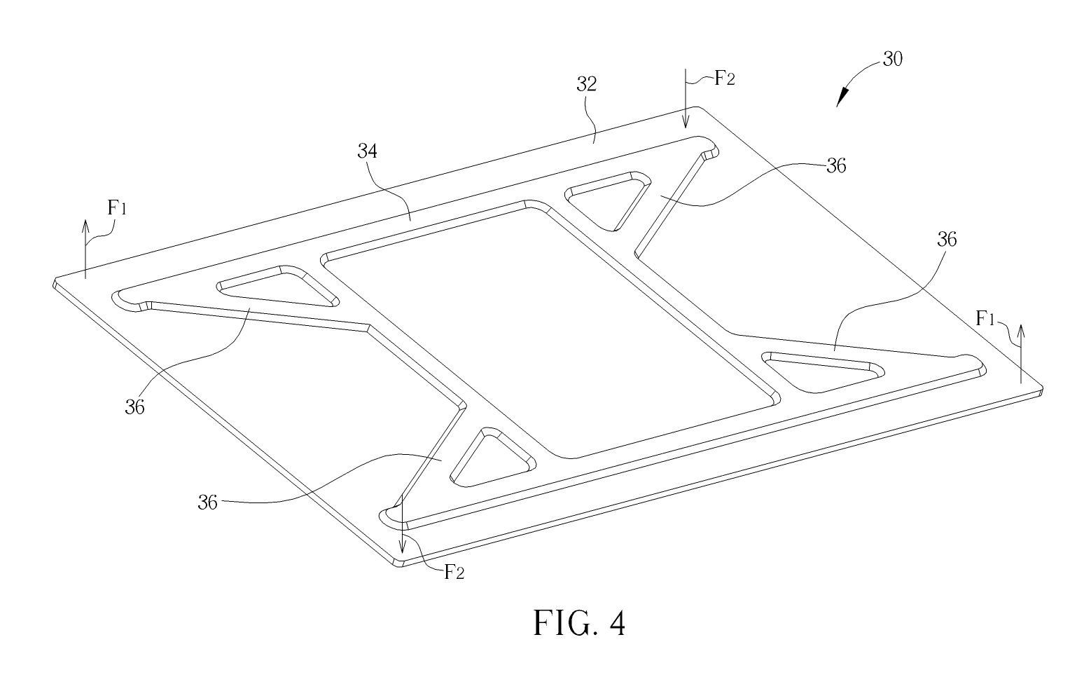

Please refer to FIG. 4. Except for the description for the embodiment in FIG. 3 of fixing the enhancing parts 26 on the back cover body 22 (or the enhancing rib 24) by blind rivets, rivets, or screws or by welding, in the back cover 30 of a second embodiment in FIG. 4, the enhancing parts 36 are formed together with the enhancing rib 34 on the back cover body 32 by stamping the back cover body 32. The feature of the positions and extension directions of the enhancing parts 36 on the back cover body 32 is similar to that in the first embodiment in FIG. 3 and will not be described herein. In this case, the enhancing parts 36 formed on the back cover body 32 also can enhance the anti-bending ability of the back cover body 32.

For example, the four corners of the back covers 20 and 30 (and panel bodies carried thereon) in FIGS. 2 through 4 are loaded with vertical external forces in directions F1 and F2 as shown in the figures for the simulation of the anti-bending ability of the back covers 20 and 30 when loaded with external force. The extension direction of the enhancing parts 26 and 36 on the back cover bodies 22 and 32 is described in the above. For more detail, the enhancing parts 26 and 36 extend on the back cover bodies 22 and 32 in a radial direction; the included angles θ between the enhancing parts 26 and 36 and the long edges 221 of the back cover bodies 22 and 32 (or a horizontal axis L represented by the long edges 221) are preferred to be from 27 to 50 degrees. When the four corners are loaded with the vertical forces of 10 kgF in the directions F1 and F2, the enhancing parts 26 and 36 can disperse the external forces on the corners effectively so as to reduce the bending extent of the back cover bodies 22 and 32. As shown by the data in the following table, when a back cover body without any enhancing part is loaded with vertical external forces in the directions F1 and F2, the maximum displacement of the corners may reach 470 mm; when the enhancing parts 26 and 36 are added on the back cover, the maximum displacement is reduced to about a half of the original obviously. Furthermore, as shown by the table, when the included angle θ is 30 degrees, the enhancing parts 26 and 36 can perform the best anti-bending ability.

| | maximum displacement of the back |
|---|---|
| | cover body loaded with forces (mm) |
| without any enhancing part | 470 |
| with enhancing parts | 250 |
| (θ = 15 degrees) | |
| with enhancing parts | 193 |
| (θ = 20 degrees) | |
| with enhancing parts | 159 |
| (θ = 25 degrees) | |
| with enhancing parts | 87 |
| (θ = 30 degrees) | |
| with enhancing parts | 127 |
| (θ = 45 degrees) | |
| with enhancing parts | 139 |
| (θ = 50 degrees) | |

Furthermore, as shown by FIG. 3, the back cover body 22 with the enhancing parts 26 can be combined directly through the enhancing part 26 with a wall-mount support. For example, a wall-mount support 263 is disposed on the first end 261 of each enhancing part 26. These wall-mount supports 263 can be used for mounting the back cover 20 (or a flat panel display including the back cover 20) on a wall.

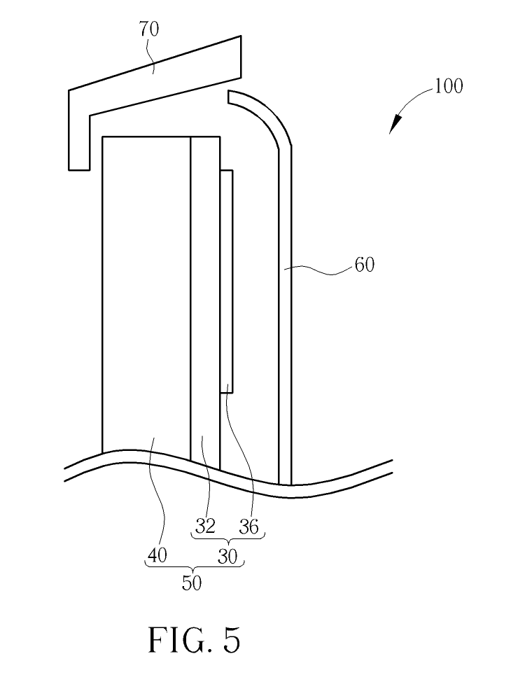

Please refer to FIG. 5, which is a partial sectional view of a flat panel display 100 of an embodiment according to the invention. The flat panel display 100 includes a panel module 50, a rear cover 60, and a front frame 70. Other components, which are not shown in FIG. 5 but belong to the necessaries of the flat panel display 100, are known easily by a skilled person in the field and are omitted herein for simple illustration. The panel module 50 includes a panel body 40 and a back cover 30; therein, the panel body 40 is fixed in the back cover 30, and the back cover 30 includes the back cover body 32 and the enhancing parts 36. The back cover 30 herein is similar to that in the third embodiment in FIG. 4, so the structural details thereof are not repeated herein. Because the enhancing parts 36 (or together with the enhancing rib 34) are formed on the back cover body 32 by stamping, the advantage of cost down and lightness and thinness of the host can be achieved. The rear cover 60 of the flat panel display 100 is joined on a side of the back cover 30 of the panel module 50. The front frame 70 is disposed to sleeve the panel module 50.

For the back cover for panel module of the invention and the flat panel display having the back cover, a plurality of enhancing parts are disposed on the back cover body of the back cover. The enhancing parts extend in a radial form from the intersections of the dashed lines trisecting the long edges and the wide edges of the back cover body respectively to the corners of the back cover body. The enhancing parts are fixed on the back cover body or the enhancing rib on the back cover body by screws or are formed together with the enhancing rib on the back cover body by stamping the back cover body. Thereby, when the flat panel display develops toward large size and thinness, the enhancing parts on the back cover body can enhance the rigidity and anti-bending ability of the back cover body.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A back cover for a panel module, comprising:
a back cover body comprising a plurality of fixing portions, a perpendicular distance from each fixing portion to a neighboring long edge of the back cover body being about one-third of a length of a wide edge of the back cover body, a perpendicular distance from each fixing portion to a neighboring wide edge of the back cover body being about one-third of a length of along edge of the back cover body; and
a plurality of enhancing parts, each enhancing part having a first end and a second end, the first end and the second end of each enhancing part being fixed at one of the fixing portions and a neighboring corner of the back cover body respectively.

2. The back cover of claim 1, wherein the back cover body further comprises an enhancing rib, and the enhancing parts are fixed on the enhancing rib.

3. The back cover of claim 2, wherein the enhancing parts and the enhancing rib are formed on the back cover body by stamping the back cover body.

4. The back cover of claim 2, wherein the enhancing parts are fixed on the enhancing rib by blind rivets, rivets, or screws or by welding.

5. The back cover of claim 1, wherein an included angle between an extension direction of each enhancing part on the back cover body and the long edge of the back cover body is from 27 to 50 degrees.

6. The back cover of claim 1, wherein the enhancing parts are made of galvanized steel, stainless steel, aluminum, or plastic steel.

7. The back cover of claim 1, wherein the first end of each enhancing part has a wall-mount part, and the back cover is capable of being mounted on a wall by use of the wall-mount parts of the enhancing parts.

8. A flat panel display, comprising:
a panel module, comprising:
a panel body; and
a back cover, the panel body being fixed in the back cover, the back cover comprising:
a back cover body comprising a plurality of fixing portions, a perpendicular distance from each fixing portion to a neighboring long edge of the back cover body being about one-third of a length of a wide edge of the back cover body, a perpendicular distance from each fixing portion to a neighboring wide edge of the back cover body being about one-third of a length of a long edge of the back cover body; and
a plurality of enhancing parts, each enhancing part having a first end and a second end, the first end and the second end of each enhancing part being fixed at one of the fixing portions and a neighboring corner of the back cover body respectively; and
a rear cover joined to a side of the back cover of the panel module.

9. The flat panel display of claim 8, wherein the back cover body further comprises an enhancing rib, and the enhancing parts are fixed on the enhancing rib.

10. The flat panel display of claim 9, wherein the enhancing parts and the enhancing rib are formed on the back cover body by stamping the back cover body.

11. The flat panel display of claim 9, wherein the enhancing parts are fixed on the enhancing rib by blind rivets, rivets, or screws or by welding.

12. The flat panel display of claim 8, wherein an included angle between an extension direction of each enhancing part on the back cover body and the long edge of the back cover body is from 27 to 50 degrees.

13. The flat panel display of claim 8, wherein the enhancing parts are made of galvanized steel, stainless steel, aluminum, or plastic steel.

14. A back cover for a panel module, comprising:
a back cover body comprising a plurality of fixing portions, a perpendicular distance from each fixing portion to a neighboring edge of the back cover body being about one-third of a length of the back cover body along the perpendicular distance; and
a plurality of enhancing parts, each enhancing part having a first end and a second end, the first end and the second end of each enhancing part being fixed at one of the fixing portions and a neighboring corner of the back cover body respectively.

15. The back cover of claim 14, wherein the back cover body further comprises an enhancing rib, and the enhancing parts are fixed on the enhancing rib.

16. The back cover of claim 15, wherein the enhancing parts and the enhancing rib are formed on the back cover body by stamping the back cover body.

17. The back cover of claim 15, wherein the enhancing parts are fixed on the enhancing rib by blind rivets, rivets, or screws or by welding.

18. The back cover of claim 14, wherein an included angle between an extension direction of each enhancing part on the back cover body and the edge of the back cover body is from 27 to 50 degrees.

19. The back cover of claim 14, wherein the enhancing parts are made of galvanized steel, stainless steel, aluminum, or plastic steel.

20. The back cover of claim 14, wherein the first end of each enhancing part has a wall-mount part, and the back cover is capable of being mounted on a wall by use of the wall-mount parts of the enhancing parts.
